(19) United States
(12) Patent Application Publication
(10) Pub. No.: US 2025/0021857 A1
(43) Pub. Date: Jan. 16, 2025

(54) PROCESSING OF QUANTUM PROGRAMS

(71) Applicant: Classiq Technologies LTD., Tel Aviv (IL)

(72) Inventors: Amir Naveh, Haifa (IL); Shmuel Ur, Shorashim (IL); Yehuda Naveh, Tel-Aviv Yafo (IL); Ofek Kirzner, Haifa (IL); Ravid Alon, Tel Aviv (IL); Tal Goren, Kibbutz Nahsholim (IL); Adam Goldfeld, Kiryat Motzkin (IL); Nir Minerbi, Haifa (IL)

(21) Appl. No.: 18/746,615

(22) Filed: Jun. 18, 2024

Related U.S. Application Data
(63) Continuation-in-part of application No. 17/450,584, filed on Oct. 12, 2021, now Pat. No. 12,073,291.

(51) Int. Cl. G06N 10/20; G06F 30/27

(52) U.S. Cl. CPC G06N 10/20; G06F 30/27

(57) ABSTRACT

A method, apparatus and product comprising: obtaining a Directed Cycle Graph (DAG) representation of a quantum program, the DAG representation comprises at least one non-executable node that represents a functionality in a high-level representation; generating a Constraint Satisfaction Problem (CSP) model of the DAG representation; generating a partial DAG representation of the quantum program based on the DAG representation, the partial DAG representation comprising at least a first executable node and a second non-executable node, said generating comprising selecting the first executable node and the second non-executable node as implementations of the at least one non-executable node; and synthesizing the quantum program based on the partial DAG representation.

### CROSS-REFERENCE TO RELATED APPLICATIONS

This application is a Continuation In Part of and claims the benefit of U.S. patent application Ser. No. 17/450,584 filed Oct. 12, 2021, titled “FUNCTIONAL-LEVEL PROCESSING COMPONENT FOR QUANTUM COMPUTERS”, which is hereby incorporated by reference in its entirety without giving rise to disavowment.

### TECHNICAL FIELD

The present disclosure relates to quantum computing in general, and to processing and compiling quantum programs, in particular.

### BACKGROUND

Quantum computing is a computational paradigm that is fundamentally different from classic computing. In contrast to classic computing, which utilizes bits, quantum computing utilizes qubits. The qubits have unique features, as each qubit can be in superposition, several qubits can be entangled, and all operations on qubits, referred to as quantum gates, must be reversible (e.g., besides measurements). Temporarily computed values are stored on additional helper qubits, referred to herein as auxiliary qubits or ancillary qubits.

### BRIEF SUMMARY

One exemplary embodiment of the disclosed subject matter is a method comprising: obtaining a Directed Cycle Graph (DAG) representation of a quantum program, the DAG representation comprises a plurality of nodes and one or more edges, the plurality of nodes comprises at least one non-executable node that represents a functionality in a high-level representation, the at least one non-executable node is not executable over a quantum execution platform, the high-level representation comprising a first level of granularity, the one or more edges indicates precedence constraints between the plurality of nodes; generating a Constraint Satisfaction Problem (CSP) model of the DAG representation, the CSP model representing the quantum program using variables, domains, and constraints on values of the variables; generating a partial DAG representation of the quantum program based on the DAG representation, the partial DAG representation comprising at least a first executable node and a second non-executable node, the first executable node is in a second level of granularity greater than the first level of granularity, said generating comprising executing a CSP solver over the CSP model, wherein said executing comprises selecting the first executable node and the second non-executable node as implementations of the at least one non-executable node; and synthesizing the quantum program based on the partial DAG representation, said synthesizing comprises determining a gate-level implementation of the quantum program based on the partial DAG representation, thereby obtaining a synthesized quantum circuit.

Optionally, said synthesizing comprises: generating a second CSP model of the partial DAG representation; generating a second partial DAG representation of the quantum program based on the partial DAG representation, the second partial DAG representation comprising an executable gate-level implementation of the second non-executable node, the executable implementation is in the second level of granularity, said generating the second partial DAG representation comprising executing the CSP solver over the second CSP model, wherein said executing comprises selecting the executable gate-level implementation for implementing the second non-executable node; and synthesizing the quantum program based on the second partial DAG representation.

Optionally, the second non-executable node is in the first level of granularity, said synthesizing comprises: generating a second CSP model of the partial DAG representation; generating a second partial DAG representation of the quantum program based on the partial DAG representation, the second partial DAG representation comprising an implementation of the second non-executable node in a third level of granularity, the third level of granularity is a higher level of granularity that the first level of granularity, the third level of granularity is a lower level of granularity that the second level of granularity, said generating the second partial DAG representation comprising executing the CSP solver over the second CSP model, wherein said executing comprises selecting the implementation of the second non-executable node; and synthesizing the quantum program based on the second partial DAG representation.

Optionally, said synthesizing the quantum program comprises iteratively executing the CSP solver over CSP models that are generated to represent the quantum program, wherein said iteratively executing is performed until obtaining valuations of all the variables from the domains, the valuations comply with the constraints, wherein the valuations represent the gate-level implementation of the quantum program in the second level of granularity.

Optionally, the method further comprises scheduling the first executable node and the second non-executable node over a space of qubits and cycles, wherein said scheduling configures the first executable node and the second non-executable node to share one or more auxiliary qubits.

Optionally, said selecting comprising selecting a partial DAG level of granularity for implementing the at least one non-executable node, the partial DAG level of granularity comprises a second plurality of nodes, the second plurality of nodes comprising at least the first executable node and the second non-executable node.

Optionally, the first level of granularity comprises a DAG level of granularity, wherein an implementation of a DAG node in the first level of granularity comprises an implementation that is not executable, wherein the implementation of the DAG node comprises a second DAG having a second plurality of nodes, the second plurality of nodes is not executable.

Optionally, the first level of granularity comprises a partial DAG level of granularity, wherein an implementation of a DAG node in the first level of granularity comprises a second DAG having a second plurality of nodes, the second plurality of nodes comprise a first portion that is executable and a second portion that is not executable.

Optionally, the second level of granularity comprises a gate-level granularity that is executable over the quantum execution platform.

Optionally, the implementations of the at least one non-executable node are selected from a library of implementations, the library comprises implementations of the functionality in different levels of granularity, the different levels of granularity comprising at least the first and second levels of granularity.

Optionally, the different levels of granularity comprise a third level of granularity, wherein the first level of granularity is a DAG level of granularity and the third level of granularity is a partial DAG level of granularity.

Optionally, the second non-executable node is in the first level of granularity or in the third level of granularity.

Optionally, the constraints comprise hardware constraints of the quantum execution platform over which the synthesized quantum circuit is scheduled to be executed.

Optionally, said obtaining the DAG representation comprises obtaining the quantum program and compiling the quantum program to obtain the DAG representation.

Optionally, the method further comprises executing the synthesized quantum circuit on the quantum execution platform.

Another exemplary embodiment of the disclosed subject matter is a computer program product comprising a non-transitory computer-readable medium retaining program instructions, which program instructions, when executed by a processor, cause the processor to: obtain a DAG representation of a quantum program, the DAG representation comprises a plurality of nodes and one or more edges, the plurality of nodes comprises at least one non-executable node that represents a functionality in a high-level representation, the at least one non-executable node is not executable over a quantum execution platform, the high-level representation comprising a first level of granularity, the one or more edges indicates precedence constraints between the plurality of nodes; generate a CSP model of the DAG representation, the CSP model representing the quantum program using variables, domains, and constraints on values of the variables; generate a partial DAG representation of the quantum program based on the DAG representation, the partial DAG representation comprising at least a first executable node and a second non-executable node, the first executable node is in a second level of granularity greater than the first level of granularity, said generate comprising executing a CSP solver over the CSP model, wherein said executing comprises selecting the first executable node and the second non-executable node as implementations of the at least one non-executable node; and synthesize the quantum program based on the partial DAG representation, said synthesize comprises determining a gate-level implementation of the quantum program based on the partial DAG representation, thereby obtaining a synthesized quantum circuit.

Yet another exemplary embodiment of the disclosed subject matter is an apparatus comprising a processor and coupled memory, said processor being adapted to: obtain a DAG representation of a quantum program, the DAG representation comprises a plurality of nodes and one or more edges, the plurality of nodes comprises at least one non-executable node that represents a functionality in a high-level representation, the at least one non-executable node is not executable over a quantum execution platform, the high-level representation comprising a first level of granularity, the one or more edges indicates precedence constraints between the plurality of nodes; generate a CSP model of the DAG representation, the CSP model representing the quantum program using variables, domains, and constraints on values of the variables; generate a partial DAG representation of the quantum program based on the DAG representation, the partial DAG representation comprising at least a first executable node and a second non-executable node, the first executable node is in a second level of granularity greater than the first level of granularity, said generate comprising executing a CSP solver over the CSP model, wherein said executing comprises selecting the first executable node and the second non-executable node as implementations of the at least one non-executable node; and synthesize the quantum program based on the partial DAG representation, said synthesize comprises determining a gate-level implementation of the quantum program based on the partial DAG representation, thereby obtaining a synthesized quantum circuit

One exemplary embodiment of the disclosed subject matter is a method comprising: generating a library of implementations of non-executable DAG nodes, wherein said generating comprises generating, for a non-executable DAG node, a set of implementations in at least two levels of granularity, the at least two levels of granularity comprise at least two of: a DAG level of granularity, a partial DAG level of granularity, and a gate-level granularity, wherein: the DAG level of granularity comprises an implementation of the non-executable DAG node in a form of a first DAG with first nodes, wherein all nodes of the first DAG are not executable over a quantum execution platform; the partial DAG level of granularity comprises an implementation of the non-executable DAG node in a form of a second DAG with second nodes, wherein a first portion of the second nodes is executable over the quantum execution platform and a second portion of the second nodes is not executable over the quantum execution platform; and the gate-level granularity comprises a gate-level implementation of the non-executable DAG node that is executable over the quantum execution platform; obtaining a selection of a node implementation from the set of implementations in a selected level of granularity, the selected level of granularity is selected from the at least two levels of granularity; and replacing the non-executable DAG node with the node implementation.

Optionally, the set of implementations comprises at least two implementations of the non-executable DAG node having a same level of granularity.

Optionally, the quantum execution platform comprises first and second quantum execution platforms, wherein the at least two implementations comprise at least first and second implementations in the gate-level granularity that are executable over the first and second quantum execution platforms, respectively.

Optionally, the selection of the node implementation is made by a CSP solver that is automatically executed over a CSP model, wherein the CSP model represents a quantum program, wherein a DAG representation of the quantum program comprises at least the non-executable DAG node.

Optionally, the non-executable DAG node is in a lower level of granularity than the gate-level granularity.

Another exemplary embodiment of the disclosed subject matter is a computer program product comprising a non-transitory computer-readable medium retaining program instructions, which program instructions, when executed by a processor, cause the processor to: generate a library of implementations of non-executable DAG nodes, wherein said generate comprises generating, for a non-executable DAG node, a set of implementations in at least two levels of granularity, the at least two levels of granularity comprise at least two of: a DAG level of granularity, a partial DAG level of granularity, and a gate-level granularity, wherein: the DAG level of granularity comprises an implementation of the non-executable DAG node in a form of a first DAG with first nodes, wherein all nodes of the first DAG are not executable over a quantum execution platform; the partial DAG level of granularity comprises an implementation of the non-executable DAG node in a form of a second DAG with second nodes, wherein a first portion of the second nodes is executable over the quantum execution platform and a second portion of the second nodes is not executable over the quantum execution platform; and the gate-level granularity comprises a gate-level implementation of the non-executable DAG node that is executable over the quantum execution platform; obtain a selection of a node implementation from the set of implementations in a selected level of granularity, the selected level of granularity is selected from the at least two levels of granularity; and replace the non-executable DAG node with the node implementation.

Yet another exemplary embodiment of the disclosed subject matter is an apparatus comprising a processor and coupled memory, said processor being adapted to: generate a library of implementations of non-executable DAG nodes, wherein said generate comprises generating, for a non-executable DAG node, a set of implementations in at least two levels of granularity, the at least two levels of granularity comprise at least two of: a DAG level of granularity, a partial DAG level of granularity, and a gate-level granularity, wherein: the DAG level of granularity comprises an implementation of the non-executable DAG node in a form of a first DAG with first nodes, wherein all nodes of the first DAG are not executable over a quantum execution platform; the partial DAG level of granularity comprises an implementation of the non-executable DAG node in a form of a second DAG with second nodes, wherein a first portion of the second nodes is executable over the quantum execution platform and a second portion of the second nodes is not executable over the quantum execution platform; and the gate-level granularity comprises a gate-level implementation of the non-executable DAG node that is executable over the quantum execution platform; obtain a selection of a node implementation from the set of implementations in a selected level of granularity, the selected level of granularity is selected from the at least two levels of granularity; and replace the non-executable DAG node with the node implementation.

### THE BRIEF DESCRIPTION OF THE SEVERAL VIEWS OF THE DRAWINGS

The present disclosed subject matter will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIG. 1 shows a flowchart diagram of a method, in accordance with some exemplary embodiments of the disclosed subject matter;

FIG. 2 shows a block diagram of an apparatus, in accordance with some exemplary embodiments of the disclosed subject matter;

FIG. 3 shows a flowchart diagram of a method, in accordance with some exemplary embodiments of the disclosed subject matter;

FIGS. 4A-4G show exemplary compilations of quantum programs, in accordance with some exemplary embodiments of the disclosed subject matter;

FIG. 5 shows a flowchart diagram of a method, in accordance with some exemplary embodiments of the disclosed subject matter; and

FIG. 6 shows a flowchart diagram of a method, in accordance with some exemplary embodiments of the disclosed subject matter.

### DETAILED DESCRIPTION

One technical problem dealt with by the disclosed subject matter is to reduce the number of resources used for an execution of a quantum circuit. In some exemplary embodiments, a user such as a programmer may generate, design, program, or the like a quantum program. In some exemplary embodiments, the quantum program may be designed using a high-level language, a functional-level code, evolutionary computing techniques such as Quantum Genetic Algorithm (QGA), genetic algorithms, or the like. In some exemplary embodiments, after an initial quantum program is created, the program may progress through multiple processing stages before becoming an executable quantum circuit that can be executed by a quantum execution platform.

In some exemplary embodiments, the processing stages through which an initial quantum program progresses may be referred to as the ‘compilation process’, and they may comprise transpilation stages, compilation stages, optimization stages, error correction stages, scheduling of compiled circuits, hardware mapping, resource allocation, or the like. In some exemplary embodiments, the compilation process of a quantum program may be performed by one or more classical computing modules of a classical computer, which may synthesize a quantum circuit that complies with hardware constraints of the quantum execution platform, such as a total number of qubits belonging to the quantum execution platform, a number and type of available gates, or the like. It is noted that the term ‘qubit’, as used herein, may refer to an individual qubit, a set of two or more qubits (e.g., a qubit register), or the like.

In some exemplary embodiments, during the compilation process, the program may progress through multiple stages. For example, a high-level program (e.g., a non-executable program) may be converted to a Directed Cycle Graph (DAG) representation. In some exemplary embodiments, nodes or vertices of the DAG may represent functional areas of the program. In some exemplary embodiments, a ‘functional area’ may refer to a logical abstraction of a circuit having one or more determined functionalities. In some cases, edges between the nodes may represent qubit dependencies, precedence constraints between the nodes, or the like. In some cases, some nodes of the DAG may be implemented in gate-level that is executable, while other nodes may comprise abstract functional area that are not executable. In some cases, all nodes of the DAG may comprise abstract functional areas that are not executable.

In some exemplary embodiments, the compilation process may comprise converting the nodes that represent functional areas to executable gate-level circuits in a defined order, until all nodes are converted to a gate-level that a quantum processor can execute. For example, in case a subset of the DAG is provided in a gate-level and a subset of the DAG is provided in high-level, only the high-level nodes may be converted to gate-level code. In some exemplary embodiments, converting the nodes to executable circuits, referred to as an ‘inline process’, may comprise allocating resources to each node, e.g., selecting a number of qubits, cycles, gates, or the like, for each node.

In some exemplary embodiments, the inline process may replace the content of each high-level node with a gate-level implementation thereof, thereby obtaining a gate-level DAG that is executable. In some exemplary embodiments, a gate-level implementation of a node may include two or more gates connected to two or more qubits. In some exemplary embodiments, the gate-level implementation may be determined, such as by selecting an implementation from implementations in a pre-prepared library, dynamically generating implementations, or the like. In some exemplary embodiments, there may be several alternative valid implementations that can be used to implement the functionality represented by a node. For example, one implementation may utilize more qubits and less cycles, while another implementation may utilize less qubits and more cycles.

In some exemplary embodiments, the inline process may select an implementation for a DAG node, e.g., from the library, based on one or more computational models, classifiers, rules, heuristics, or the like. In some exemplary embodiments, an implementation for a node may be selected based on hardware constraints, based on an optimization function, or the like. For example, the inline process may obtain hardware constraints (e.g., available hardware gates), user constraints (e.g., a desired speed/qubit ratio), circuit constraints, or the like, and generate a Constraint Satisfaction Problem (CSP) paradigm based thereon. Once a CSP modeling is provided, constraints of the CSP may be defined based on desired functionality, hardware constraints, circuit constraints, topology and architecture of the quantum circuit, or the like. After the CSP is defined, a CSP solver may be applied. In some exemplary embodiments, based on the constraints, a CSP solver may select from the library a gate-level implementation for each node in a manner that satisfies all the constraints. In other cases, any other solver or algorithm may be used instead or in addition to the CSP solver.

In some exemplary embodiments, after the inline process, the nodes' gate-level implementations may be scheduled over a space of cycles and qubits. For example, the scheduling may dictate the order of quantum operations, which operations can be executed in parallel, which operations can be executed sequentially (by reusing a same qubit), an allocation of resources per operation, or the like. In some exemplary embodiments, the scheduling of the implementations may be indicated by a result of the CSP solver, or may be calculated separately. In some exemplary embodiments, based on the selection of node implementations and schedules of the nodes, a quantum circuit may be compiled and executed on a quantum execution platform such as a quantum computer.

In some exemplary embodiments, the inline process may have one or more drawbacks. For example, the inline process may result with a compiled quantum circuit that does not necessarily optimize on resource usage. In some exemplary embodiments, a suboptimal resource utilization of a quantum circuit may cause an overall execution time of the quantum execution platform to be longer, an overall number of cycles to be greater, a number of non-utilized idle qubits at every cycle to be larger, or the like, compared to a resource utilization that is more optimal. It may be desired to reduce the resources used for an execution of a quantum program.

Another technical problem dealt with by the disclosed subject matter is enhancing a library from which the CSP solver selects node implementations. In some exemplary embodiments, the node implementations may be selected from a directory of different implementations of functional areas (referred to as ‘library’ or ‘function library’), storing viable implementations for multiple functional areas, performance parameters thereof, or the like.

In some exemplary embodiments, for known functional areas, gate-level implementations may be created and stored within the function library. In some exemplary embodiments, the function library may retain a plurality of alternative gate-level implementations for one or more defined functional areas. In some cases, one or more function libraries may correspond to one or more respective quantum execution platforms over which library implementations are executable. For example, a certain high-level functionality may be implemented for a first quantum execution platform in a first function library, and for a second quantum execution platform in a second function library. In some cases, a single function library may comprise library implementations that are executable over a plurality of different quantum execution platforms. For example, a function library may comprise library implementations of a high-level functionality that are implemented for first and second quantum execution platforms.

In some exemplary embodiments, different gate-level implementations of a functional area may have different properties, e.g., differing in a number of cycles, a number of qubits, an entanglement caused by the alternative implementation, a number of auxiliary qubits utilized by the alternative implementation, a number of cleaning operations, a hardware or precision error rate, a quantum execution platform over which the implementations are executable, or the like. In some exemplary embodiments, different implementations may optimize on different criteria. In some exemplary embodiments, a tradeoff may exist between the number of qubits and the number of cycles. For example, a first gate-level implementation of a function that utilizes a greater number of qubits compared to a second gate-level implementation of the same function, may be implemented quicker, with less cycles, and vice versa.

In some exemplary embodiments, although the library implementations may differ in their properties, they may all comprise gate-level implementations of the same functional area, function, or the like. For example, in case the functional area includes an ‘add’ operation configured to add a state of a first qubit to a state of a second qubit and store them in a third qubit, all implementations of the functional area may result with the ‘add’ function being implemented. In some exemplary embodiments, each alternative implementation of a functional area may be configured to provide a same functionality. In some exemplary embodiments, the library may be generated and utilized for the inline process in one or more manners, e.g., as disclosed in U.S. patent application Ser. No. 17/499,046 filed Oct. 12, 2021, titled “CSP-BASED SYNTHESIS OF A QUANTUM CIRCUIT”, which is herein incorporated by reference in its entirety without giving rise to disavowment.

In some exemplary embodiments, the function library may have one or more drawbacks. In some cases, a selection of a gate-level implementation from the library may not necessarily optimize the compilation globally, may not necessarily be efficient in resource allocation, or the like. For example, auxiliary qubits that are idle in some cycles of a first gate-level implementation, may not be reused by other gate-level implementations until the first gate-level implementation is completes its execution. It may be desired to overcome these drawbacks.

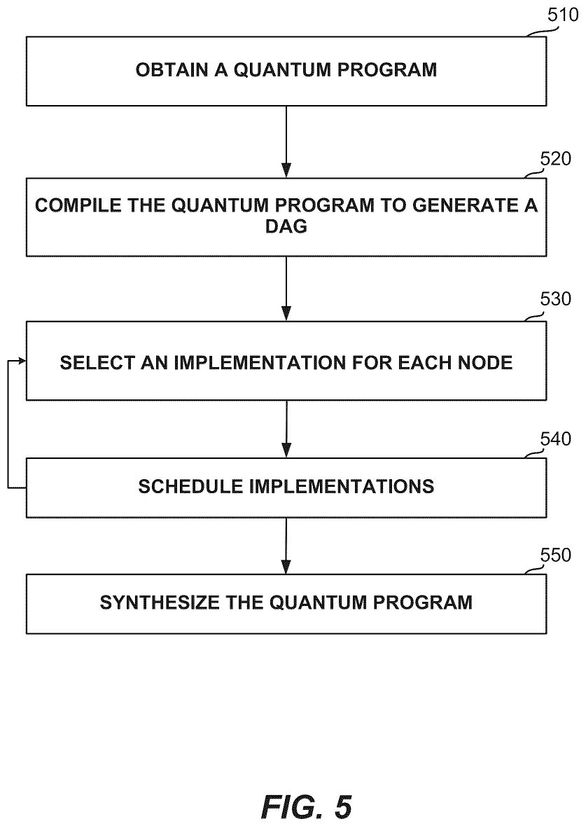

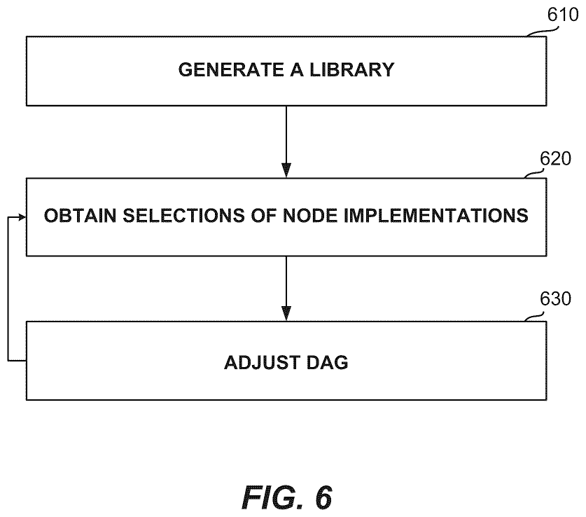

One technical solution provided by the disclosed subject matter is to provide library implementations in different granularity levels, in order to increase a flexibility of the in-line process. In some exemplary embodiments, using different granularity levels may result with an iterative process of CSP generations and executions of CSP solvers thereon. In some exemplary embodiments, the CSP solver may iteratively be executed over an initial DAG of a program until reaching a gate-level implementation of all nodes of the initial DAG, e.g., according to the methods of FIGS. 5-6.

In some exemplary embodiments, a CSP solver may refer to one or more CSP solvers that are configured to be executed subsequently and/or simultaneously on CSP models. For example, a first disjoint set of CSP solvers may be executed on a first CSP model, and a second disjoint set of CSP solvers may be executed subsequently on an adjusted version of the CSP model (e.g., resulting from the execution of the first set of CSP solvers).

In some exemplary embodiments, the function library may be adjusted to comprise, for a functional area, implementations in at least three granularity levels: a gate-level implementation, a DAG implementation, and a partial-DAG implementation. In some exemplary embodiments, a DAG implementation may constitute a lowest granularity level, a partial-DAG implementation may constitute an intermediate granularity level, and the gate-level implementation may constitute a highest granularity level. In some exemplary embodiments, partial-DAG implementations may constitute a range of granularity levels.

In some exemplary embodiments, for a lowest granularity level of a node, the node may be replaced with a DAG. In some exemplary embodiments, the node may be converted to an entire new DAG that implements the node in a high level and is not executable. For example, a DAG replacing an original node may comprise precedence constraints between components of the original node (indicates by edges), a separation of the original node to functional components (indicated by DAG nodes), or the like. In some exemplary embodiments, the original node may be converted to a DAG in which all nodes are not executable.

In some exemplary embodiments, for an intermediate granularity level of a node, the node may be replaced with a DAG that is partially in-lined. In some exemplary embodiments, the node may be converted to an entire new DAG, in which at least one node is an executable gate-level circuit, and at least one node is a high-level node that is not executable. For example, the high-level node may comprise another DAG. In some exemplary embodiments, the intermediate granularity level may range from higher granularity levels in which most nodes are executable, to lower granularity levels in which most nodes are not executable.

In some exemplary embodiments, for a highest granularity level of a node, the node may be replaced with a fully in-lined circuit that is executable. For example, the highest granularity level may correspond to the in-lining process disclosed in U.S. patent application Ser. No. 17/499,046 filed Oct. 12, 2021, titled “CSP-BASED SYNTHESIS OF A QUANTUM CIRCUIT”. In some exemplary embodiments, library implementations in the highest granularity level may be predefined by the library or dynamically generated and added to the library. For example, library implementations may be dynamically generated according to one or more methods disclosed in U.S. patent application Ser. No. 17/499,082 filed Oct. 12, 2021, titled “DYNAMIC SYNTHESIS OF GATE-LEVEL IMPLEMENTATIONS OF FUNCTIONAL BLOCKS IN QUANTUM CIRCUITS”, which is incorporated by reference herein in its entirety without giving rise to disavowment.

In some exemplary embodiments, for a single functional area or function, different viable implementations may exist in each granularity level. For example, a node representing a functional area may be implementable by two different DAG implementations in the lowest granularity level, the two DAGs differing in one or more properties such as in their precedence constraints. As another example, a node representing a functional area may be implementable by a first number of DAGs in the lowest granularity level, a second number of partial DAGs (also referred to as ‘hybrid DAGs’) in one or more intermediate granularity levels, and a third number of gate-level implementations in the highest granularity level.

In some exemplary embodiments, after adjusting the function library, the in-lining process may comprise executing a CSP solver on an increased solution space that comprises a variety of granularity levels of at least some nodes in the DAG, and one or more different implementations for each granularity level. In some exemplary embodiments, the CSP solver may be executed over an initial DAG representing a single quantum program, two or more quantum programs, or the like, and may convert the DAG to a partial-DAG or to a second DAG. For example, in case the CSP selects for each node of the initial DAG a DAG implementation, the CSP may convert the initial DAG to a second DAG that is larger, e.g., has more nodes, more edges, or the like. As another example, in case the CSP selects for at least one node of the initial DAG a gate-level implementation or a partial-DAG implementation, the CSP may convert the initial DAG to a partial-DAG that has at least one executable node.

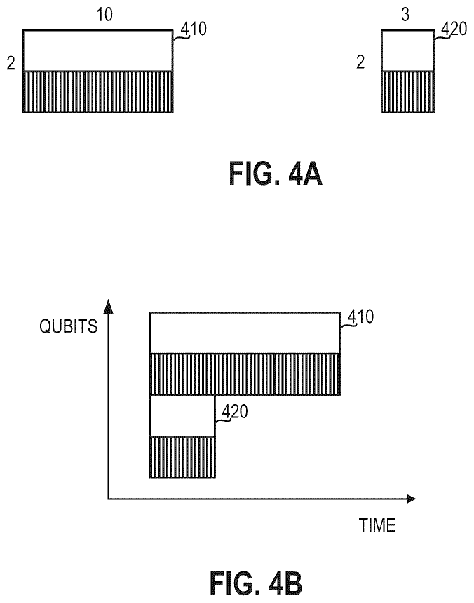

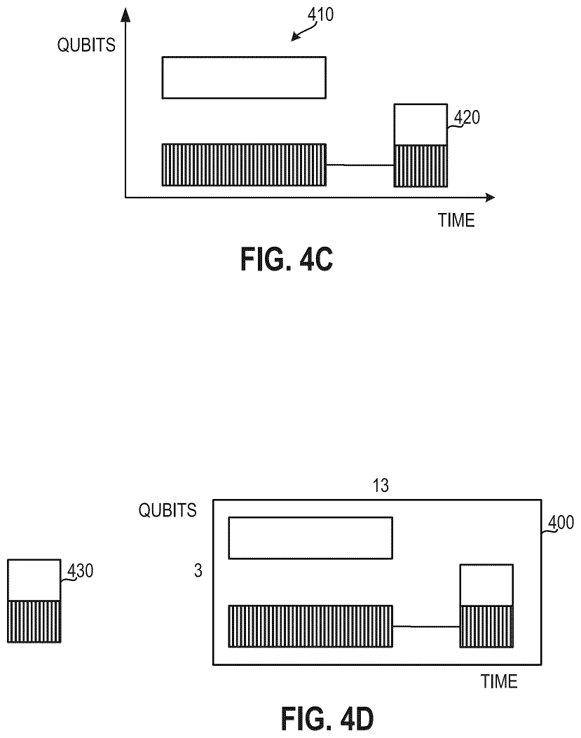

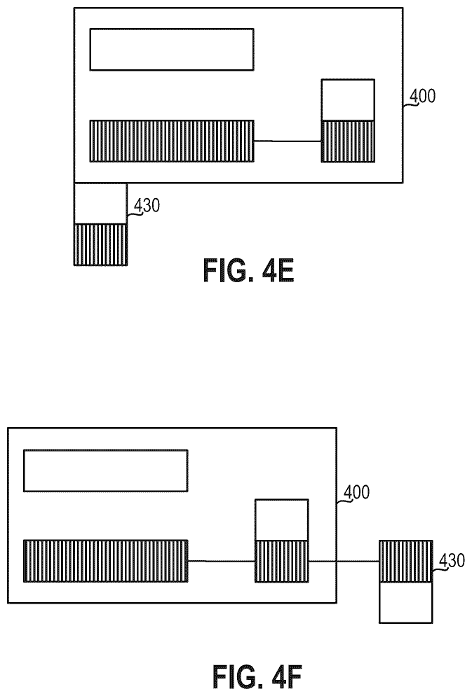

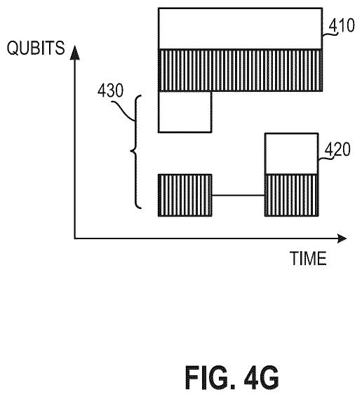

In some exemplary embodiments, the CSP solver may select a granularity level of node implementations according to one or more constraints, objective functions, optimization functions, cost functions, or the like. In some exemplary embodiments, selecting lower granularity levels, such as DAG implementations, increases the flexibility of the CSP solver, and enables to consider global constraints and resource utilizations, while requiring more computational power and time from the CSP solver. For example, in case a node utilizes auxiliary qubits for only a portion of its calculations, implementing the node in a lower granularity level can enable to eventually share the auxiliary qubits with other nodes, thereby enhancing the resource utilization of the resulting circuit. For example, FIGS. 4A-4G depict how selecting node implementations in lower granularity levels can reduce resources used for an execution of a quantum circuit.

In some exemplary embodiments, selecting higher granularity levels, such as gate-level implementations, reduces the flexibility of the CSP solver, but also reduces the computational load from the CSP solver and may provide well-known circuit-level implementations that have been tested to be efficient and well designed, have metadata regarding its resource utilization and/or performance, or the like. In some cases, gate-level implementations may be publicly available, tested offline, have accumulated performance data thereof from different users and executions, or the like, which may increase reliability of the gate-level implementations. For example, gate-level implementations may be provided along with metadata indicating their average execution times, average usages of resources, error rates, or the like.

In some exemplary embodiments, the CSP solver may balance between the benefits and drawbacks of each granularity level according to one or more parameters. For example, a user may provide a parameter indicating a number of executions that are scheduled for the program (e.g., as an objective function, constraint, or the like). In some exemplary embodiments, the CSP solver may be configured to put more effort and increase its computational load when the number of executions is large, e.g., above a threshold, and select lower granularity levels for such cases. In some exemplary embodiments, the CSP solver may determine to decrease its computational load when the number of executions is low, e.g., less a threshold, and select higher granularity levels for such cases.

In some exemplary embodiments, the CSP solver may be configured to select a granularity level for a node based on the context of the execution. In some exemplary embodiments, the CSP solver may select granularity levels for nodes based on whether or not they utilize auxiliary qubits, an estimated potential for sharing resources of each node, an objective function measuring a number of idle qubits per cycle, or the like. For example, as the potential for sharing resources is greater, the CSP solver may select lower granularity levels, and vice versa. As another example, in case hardware constraints limit the number of executions of a certain type of gate per cycle (e.g., at most 5 gates of type Hadamard per cycle), the CSP solver may select lower granularity levels, to enable better sharing of the limited gate resources between nodes.

For example, the CSP solver may determine that a node uses auxiliary qubits for 10% of its cycles and/or qubits (e.g., 10% of an area defined by cycles and qubits). The CSP solver may determine whether other nodes of the DAG also require auxiliary qubits. In case they do, the CSP solver may select an implementation for the node that is not a gate-level implementation (a DAG or partial-DAG implementation), thereby enabling the node to share its auxiliary qubit resources with other nodes. For example, FIGS. 4A-4G depict exemplary nodes that require auxiliary qubits, and how a selection of lower granularity levels may be beneficial in terms of sharing qubits.

In some exemplary embodiments, the function library may be dynamically adjusted to add additional implementations of nodes and/or DAGs in one or more granularity levels. In some exemplary embodiments, in case of a parameterized quantum program that is scheduled to be executed a large number of times with different parameters, a circuit implementation of the program that is obtained after a number of iterations of the CSP solver, may be added to the library and used as a starting point for the subsequent executions of the program. For example, gate-levels implementations of each node may be added to the library, partial DAGs for each node may be added to the library, full DAGs for each node may be added to the library, a single gate-level implementation (or of any other granularity level) of two or more nodes may be added to the library, or the like. In some cases, this may reduce the computational burden of the CSP solver due to the similarity of the program instances.

One technical effect of utilizing the disclosed subject matter is enabling to reduce the resource consumption of quantum executions, by enabling to share resources between nodes of a DAG that represents the quantum program.

Another technical solution is to increase a flexibility to the inline processing, by providing node implementations in different granularity levels.

Yet another technical solution is enabling to balance between the computational load of the CSP solver and the efficiency of the compilation process, according to a context of the execution, the number of scheduled executions, or the like.

Yet another technical solution is enhancing a function library to provide more implementation options at different granularity levels, thereby increasing a solution space of the CSP solver. The disclosed subject matter may provide for one or more technical improvements over any pre-existing technique and any technique that has previously become routine or conventional in the art. Additional technical problems, solutions, and effects may be apparent to a person of ordinary skill in the art in view of the present disclosure.

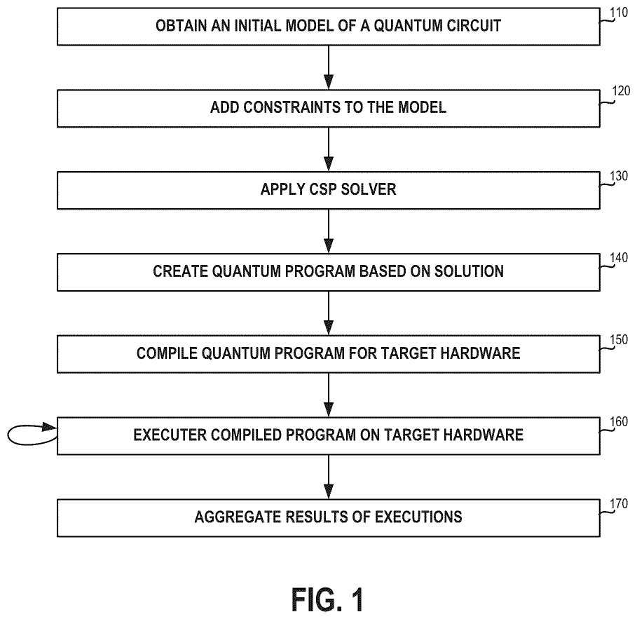

In some cases, the methods of FIGS. 1-3 may correspond to those of U.S. patent application Ser. No. 17/149,326 filed Jan. 14, 2021, titled “QUANTUM CIRCUIT MODELING”, now U.S. Pat. No. 11,288,589, which is hereby incorporated by reference in its entirety without giving rise to disavowment.

Referring now to FIG. 1 showing a flowchart diagram of a method, in accordance with some exemplary embodiments of the disclosed subject matter.

On Step 110, an initial model of a Quantum Circuit (QC) may be obtained. In some exemplary embodiments, the model may be a Constraint Satisfaction Problem (CSP) model. The CSP model may comprise a set of decision variables (x₁, x₂, . . . , xₙ), with respective domains (D₁, D₂, . . . , Dₙ), such that the value of a decision variable xi is selected from the respective domain, Di. In some exemplary embodiments, the domains may have discrete sets of values, continuous sets of values, or the like, such as but not limited to {1,2,3,4}, [0,1], integer numbers, real numbers, or the like. The CSP may comprise a list of constraints on the variables. The constraints may be expressed as logical expressions over the decision variables, Boolean expression over the decision variables, or the like, such as but not limited to x₁<x₂, x₁+x₂>5, x₄=3→x₅=1, or the like. In some exemplary embodiments, the CSP model may be solved by a satisfying assignment in which a valuation of each decision variable from its respective domain is provided, where all constraints are held. Additionally, or alternatively, the CSP model may comprise a target optimization function. In such a case, a solution to the CSP model may attempt to also provide, in addition to a satisfying assignment holding all constraints, an assignment optimizing (e.g., minimizing, maximizing, or the like), the value of the target function.

A QC can be adapted to the CSP framework in a similar way to the salesman problem. It is noted that a QC may be modeled in a plurality of different manners. Naïve modeling of a QC may be inefficient and may present a problem that the CSP solver, having NP computation complexity, may be unable to solve in reasonable time (e.g., minutes, hours, or even days). Hence, care should be taken to the modeling of the QC itself.

In some exemplary embodiments, the quantum circuit may comprise a list of gates or unitary ‘operations’ done in sequential order. Each decision variable in the model may correspond to an operation to be executed in order. Additional constraints may be added to produce a legal circuit with the required functionality.

It is noted that the model of the QC may be based on a Directed Cycle Graph (DAG) representation of the QC. Vertices in the DAG may represent gates and directed edges may represent qubit dependencies. Additionally or alternatively, the vertices may represent inputs, outputs and operations and edges may represent qubits and bits.

### Example 1: QC with a Single Qubit Operation

Some quantum hardware may support unitary operation on a single qubit gate. We exemplify this using the unitary operation U₃(θ, ϕ, λ) supported by IBM™ hardware. The U₃ operation may have 3 input parameters: theta, phi and lambda. A model comprising up to N operations may be modeled as follows:

### Decision Variables:

xᵢ∈{U₃}, i∈{0 . . . N}—gate assignment in the order 0 to N.
θᵢ∈[0,2π], i∈{0 . . . N}—angle assignment for gate i.
θᵢ∈[1,2π], i∈{0 . . . N}—second angle assignment for gate i.
λᵢ∈[0,2π], i∈{0 . . . N}—-qubit assignment for gate i.

### Example 2: Multi-Qubits Operation

In some exemplary embodiments, in order to include a 2-qubits operation additional constraints may be utilized. As an example of a 2-qubits operation, we refer to a controlled not (CX) operation. For the avoidance of doubt other quantum gates may also be referred to such as but not limited to Rx, Ry, Rz, T, S, or the like, and the description relates to CX for clarity of disclosure and without limiting the scope of the disclosed subject matter.

One exemplary modeling may be as follows:

### Decision Variables:

xᵢ∈{U₃,CX}, i∈{0 . . . N}—gate assignment in the order 0 to N.
θᵢ∈[0,2π], i∈{0 . . . N}—angle assignment for gate i.
ϕᵢ∈[0,2π], i∈{0 . . . N}—second angle assignment for gate i.
λᵢ∈[0,2π], i∈{0 . . . N}—third angle assignment for gate i.
q1ᵢ∈{1 . . . k}, i∈{0 . . . N}—qubit assignment for gate i.
q2ᵢ∈{0 . . . k}, i∈{0 . . . N}—second qubit assignment for gate i.

### Constraints:

$$\begin{matrix}1. & \\ ∀ i , {x}_{i} = {U}_{3} ⇔ q {1}_{1} = 0 & \end{matrix}$$

$$\begin{matrix}2. & \\ ∀ i , q {1}_{i} \neq q {2}_{i} & \end{matrix}$$

In this example, a second assignment qubit decision variable is added. The second assignment variable is active (not zero) for CX gate type (constraint 1). The qubits assignments must be different—q1ᵢ is the target and q2ᵢ is the control qubit (constraint 2).

A satisfying assignment of such model represents a quantum circuit to be built. If the value of a decision variable q2; is zero, such variable is ignored in the construction of the circuit itself.

In some exemplary embodiments, this format may be generalized for operation on more than two qubits. The order of qubits assignment may define how to apply the operation—for example, a three-qubit gate where each input behaves differently, the assignment order [1,2,3] and [1,3,2] may have different functionality.

### Example 3: DAG Based Model

A DAG-based modeling may be utilized, in which the decision variables may represent vertices and edges in the DAG, and constraints may ensure desired properties. As an example, consider a DAG representation in which vertices are gated and qubit dependencies are represented by edges.

### Decision Variables:

xᵢ∈{U₃,CX}, i∈{0 . . . N}—gate assignment in up to N gates of the QC.
θᵢ∈[0,2π], i∈{0 . . . N}—angle assignment for gate i.
ϕᵢ∈[0,2π], i∈{0 . . . N}—second angle assignment for gate i.
λᵢ∈[0,2π], i∈{0 . . . N}—third angle assignment for gate i.
edge_inᵢ ∈{x₀ . . . x_{N}}, i∈{0 . . . N} and edge_outᵢ∈{x₀ . . . x_{N}}, i∈(55 0 . . . M)—defining up to M edges (edge_inᵢ, edge_outᵢ).

### Constraints:

$$\begin{matrix}1. & \\ ∀ i , edge\_out = {x}_{k} \to reachable ( {x}_{k} , {edge\_in}_{i} ) & \end{matrix}$$

$$\begin{matrix}2. & \\ ∀ i , {x}_{i} = {U}_{3} ⇔ ∃ j {edge\_out}_{j} = {x}_{i} ∧ {∀}_{k \neq j} {edge\_out}_{k} \neq {x}_{i} & \end{matrix}$$

$$\begin{matrix}3. & \\ ∀ i , {x}_{i} = C X ⇔ ∃ {j}_{1} , \\ {j}_{2} {edge\_out}_{{j}_{1}} = {x}_{i} ∧ {edge\_out}_{{j}_{2}} = {x}_{i} ∧ {∀}_{k \neq {j}_{1} ∧ k \neq {j}_{2}} {edge\_out}_{k} \neq {x}_{i} & \end{matrix}$$

In some exemplary embodiments, a reachable predicate (a,b) may indicate whether b is reachable using one or more edges from vertex a. The first constraint ensures the model is acyclic. The second constraint, ensures a single qubit assignment for a U₃ gate, while the third constraint ensures that each CX gate is assigned exactly two qubits.

In some exemplary embodiments, M and N may be based on decision variables enabling to a dynamic size of the model. Additionally or alternatively, some threshold limits may be utilized as M and N. In such a case, the domain of xᵢ may include a dummy gate, and the domains of the edge_in and edge_out may include dummay values for dummy edges. In some cases, a constraint may ensure that is a dummy value is in one sides of an edge, the other side of the edge is also a dummy value (e.g., ∀ᵢedge_outᵢ; =I↔edge_inᵢ=I).

### Example 4: Multi-Qubits Operation 2

Additionally, or alternatively, a more compact representation may be used to model multi-qubit operations without the use of additional qubits decision variables (q₂, q₃, etc.). This way the model is more compact, with fewer variables than the previous modeling. It is noted that the constraints may be relatively more complicated than in the previous modeling, which may increase computation time of the CSP solver (e.g., during constant propagation phases).

### Decision Variables:

xᵢ∈{U₃,CX}, i∈{0 . . . N}—gate assignment in the order 0 to N.
θᵢ∈[0,2π], i∈{0 . . . N}—angle assignment for gate i.
ϕᵢ∈[0,2π], i∈{0 . . . N}—second angle assignment for gate i.
λᵢ∈[0,2π], i∈{0 . . . N}—third angle assignment for gate i.
q1ᵢ∈{1 . . . k}), i∈{0 , . . . N}—second qubit assignment for gate i.

### Constraints:

$$\begin{matrix}1. & \\ ∀ i , {x}_{i} = C X \to ( {x}_{i - 1} = I ∧ {x}_{i + 1} = CX ∧ {x}_{i + 2} = I ) ∨ ( {x}_{i - 2} = I ∧ {x}_{i - 1} = CX ∧ {x}_{i + 1} = I ) & \end{matrix}$$

$$\begin{matrix}2. & \\ ∀ i , {x}_{i} = CX ∧ {x}_{i + 1} = C X \to {q}_{i} \neq {q}_{i + 1} & \end{matrix}$$

In this modeling, a dummy value (I) is introduced. The dummy value (e.g., identity gate) may be utilized as a separator and may not correspond to any logical functionality. The first constraint ensures that CX gate is assigned in consecutive groups of two, separated by a separator before the group and after the group. The qubit assignment for the first CX gate of the group corresponds to q₁ in the previous model, while the second assignment corresponds to q2. The second constraint makes sure that two different qubits are assigned to the gate (e.g., q1≠q2).

### Example 5: Block\Cycle

In some exemplary embodiments, the modeling may comprise a block\cycle format. A block may comprise a subset of qubits over a subset of the cycles, and may be aimed at providing a functionality. In some exemplary embodiments, a block may be a vertical cut of the quantum circuit. In the present proposed modeling it is clear how to separate the QC to blocks by addressing a group of cycles. In the previously presented modeling, which utilized linear format, addressing a block may be harder and bug-prone.

In some exemplary embodiments, gate assignment is defined by an array of variables, where each column is a cycle, and each row is a qubit. This facilitates writing constraints between blocks of algorithmic sections.

### Decision Variables:

x_{i,j}∈{I,U₃, CX},i∈{0 . . . N},j∈{1 . . . k}—gate assignment in the i-th cycle, for qubit
θ_{i,j}∈[0,2π], i∈{0 . . . N}—angle assignment for cycle i, qubit j.
ϕ_{i,j}∈[0,2π], i∈{0 . . . N}—second angle assignment for cycle i, qubit j.
λ_{i,j}∈[0,2π], i∈{0 . . . N}third angle assignment for cycle i.
control_qubit_{i,j}∈{0, . . . k}, i∈{0 . . . N}, j∈{1 . . . k}—marks to which qubit j the gate controls connected to on cycle i. For example, for CX, control_qubit_{1,2}=3 means that on cycle 1 qubit 2 is controlling qubit 3. If the qubit is controlled, the value is set to be zero. In this example, on cycle 1, for qubit 3, the value is 0 (control_qubit_{1,3}=0).

### Constraints:

$$\begin{matrix}1. & \\ ∀ i , j , {x}_{i , j} = C X ↔ {control\_qubit}_{i , j ,} \neq j ∧ {control\_qubit}_{i , j ,} \neq 0 & \end{matrix}$$

$$\begin{matrix}2. & \\ ∀ i , j {control\_qubit}_{i , j} \neq j \to {x}_{l , {control \_ qubit}_{i , j}} = I ∧ {control\_qubit}_{i , {control \_ qubit}_{i , j}} = 0 & \end{matrix}$$

$$\begin{matrix}3. & \\ ∀ i , ∀ m \neq n s . t . {control\_qubit}_{i , m} \neq 0 , {control\_qubit}_{i , m} \neq {control\_qubit}_{i , n} & \end{matrix}$$

$$\begin{matrix}4. & \\ ∀ i , j {control\_qubit}_{i , j} = 0 \to exist ( {control\_qubit}_{i , m} = j ) & \end{matrix}$$

These constraints may be aimed to ensure that the CX two qubit gate is assigned correctly. Constraint 1 requires that if a CX gate is assigned to a specific qubit, that qubit controls someone (other than itself). Constraint 2 requires that if a qubit controls another qubit, the controlled qubit itself does not have a gate assignment (assigned the dummy gate, I) and that qubit is indicated as controlled by someone else (control_qubit value assigned to be zero). Constraint 3 is aimed to ensure that the controller qubit is unique, such that no two qubits are controlled by the same qubit. Constraint 4 requires that if a qubit is indicated as being controlled, another qubit will be indicated as controlling it.

In such a modeling, referring to blocks may be relatively easy. Consider the following example. Assume a naïve error model where there is a 2% error chance on CX gates and the designer wants at least 66% success rate on each qubit measurement, meaning that no error occurred for that qubit on any of the gates. Meaning that the total of CX gate allowed on a qubit is 20 (0.98²⁰=0.667). The following constraint (denoted constraint 5) may count the number of times a qubit is utilized in a CX gate (either as controlling, and then the relevant xᵢⱼ decision variable is set to CX, or as being controlled, and then the control_qubit_{i,j} decision variable is set to zero. Constraint 5 requires that for each qubit, CX gate is applied on the qubit up to 20 times.

$$\begin{matrix}5. & \\ ∀ j , {Σ}_{i} {1}_{\{ {x}_{i , j} = C X \}} + {1}_{\{ {control \_ qubit}_{i , j} = 0 \}} \leq 20 & \end{matrix}$$

The circuit may be split into two blocks. The first block may comprise the first M1 cycles and the second block may comprise the last M2 cycles. Different constraints may be applied on the different blocks, including constraints that would allow the size of the blocks to be dynamically set by the CSP solver.

Consider the following example. Assume the circuit first M1 cycles are for preparing a quantum state that can have up to 10% error. Hence, for those M1 cycles, the number of times CX is applied on the qubit is limited to up to 5 times using constraint 6:

$$\begin{matrix}6. & \\ ∀ j , {Σ}_{i < M 1} {1}_{\{ {x}_{i , j} = C X \}} + {1}_{\{ {control \_ qubit}_{i , j} = 0 \}} \leq 5 & \end{matrix}$$

Assume in the last M2 cycles, only 2 phases can be used for some functionality. A constraint such as constraint 7 ensures that such property is held in the last M2 cycles:

$$\begin{matrix}7. & \\ ∀ j , {Σ}_{i > N - M 2} {λ}_{i , j} = 0 & \end{matrix}$$

The initial model obtained on Step 110 may be obtained from a user, from a repository, from a third-party, or the like. As an example, the user may utilize a human-machine interface (HMI), such as a textual interface or a graphical interface, to express the constraints on the quantum circuit. For example, the user may be given a textual interface in which the user can write constraints and constraint packages. The constraints may relate to any aspect of the quantum circuit, including but not limited to: number of qubits, number of two-qubit gates, circuit depth (e.g., minimal depth, maximal depth), number of single qubit gates from each type, error metric and error range for some or all qubits, connections between qubits and qubit registers (e.g. two registers must be entangled by some minimal value), specific states the system should be in at specific places in the circuit, or the like. Additionally, or alternatively, the constraints may include functionality constraints indicating that the circuit or sub-circuit needs to perform some specified functionality. For example: Add two registers, entangle some subset of qubits, load some value to a specific register, or the like.

In some exemplary embodiments, quantum related constraints may be provided using a defined language that may abstract some of the implementation details of the model from the user. Consider the following constraints:

$$\begin{matrix}1. & \\ circuit = QuantumCircuit ( qubits\_count = 4 , min\_depth = 2 , max\_depth = 5 ) & \end{matrix}$$

$$\begin{matrix}2. & \\ circuit . phase\_cx \_slide \_entangler = PhaseCXSlideEntangler ( uniform , \\ slide\_first \_control = 0 , slide\_targets = ( 1 , 2 ) , phase = 2 ) & \end{matrix}$$

$$\begin{matrix}3. & \\ circuit . cx\_slide \_entagler = CXSlideEntangler ( slide\_first \_control = 1 , slide\_targets = ( 2 , 3 ) ) & \end{matrix}$$

QuantumCircuit, PhaseCXSlideEntangler, CXSlideEntangler are all constructs that are defined in the language performing some specific functionality. In some exemplary embodiments, QuantumCircuit may be a construct that complies to the general quantum circuit constraints, such as depth and number of qubits. Additionally, or alternatively, PhaseCXSlideEntangler may be a construct that creates entanglement between several qubits with a phase. Additionally, or alternatively, CXSlideEntangler may be a construct that creates entanglement between several qubits without a phase. In some exemplary embodiments, each of these constructs may map to a set of constraints on the variables that model the quantum circuit.

On Step 120, additional constraints may be added to the model in an automated manner. The determination of additional constraints may be made depending on the algorithm implemented by the quantum circuit, the hardware being utilized, expected running time, space usage, or the like.

As an example, constraints relating to the usage of auxiliary qubits may be introduced to the model. In some exemplary embodiments, an auxiliary qubit may be a qubit which start at the zero state, at a known state, or the like, and is used for temporary computations. In some exemplary embodiments, the CSP can also control the use of auxiliary qubits and reuse them in a different part of the circuit by keeping a flag variable for auxiliary usage. A decision variable may be added for each qubit indicating if it is auxiliary in each cycle. The CSP constraints can assign a value to keep track of this and using this information, gates that require auxiliary qubits can select different qubits to be used, or the like. It is noted that in some embodiments, it may be known which are the auxiliary qubits by design. However, extrapolating such information by a compiler may require substantive computations, such as executing simulation of the design. The disclosed subject matter may allow for the model to indicate which are the auxiliary qubits and enforce efficient usage thereof.

In some exemplary embodiments, global constraints may be introduced to the model, which may be utilized to determine which combination of algorithms implementation are used, the hardware, the running time and space usage, or the like. For example, phase estimation may be implemented using two alternative algorithms. One may be by the use of quantum Fourier transform, while the other uses multiples measurement and offline post processing. The Fourier transform may be faster but may not comply with a desired error score, while the second method is slower, it may be less prone to error. As another example, two alternative implementations of a gate may provide a different space complexity. In some exemplary embodiments, a first implementation may require a number of gates that is linear in the number of qubits but may use auxiliary qubits, while the second may require O(n²) gates but may avoid the use if any auxiliary qubits. As yet another example, there may be hardware considerations to the quantum circuit, which may be imported into the model automatically based on the type of the target hardware platform. In some exemplary embodiments, an operation that is not native to the quantum execution platform may get broken to sub-operations, resulting in a different number of gates depending the hardware. The number of gates affect the time it takes to run and error. In some exemplary embodiments, by introducing hardware-related considerations to the design phase, the resulting quantum circuit may be handled better by the compiler, such as by resulting in a compiled circuit that has improved runtime and reduced error rate, with respect to a naïve implementation in which the specific hardware is not considered at all.

On Step 130, a CSP solver may be applied on the model to provide a solution for the CSP. In case no solution is available, an UNSAT indication may be provided and the user may be informed that the requirements cannot be met. If there is a solution available, the CSP solver may provide such solution. It is noted that the CSP solver may utilize different techniques to provide a solution. In some exemplary embodiments, the CSP solver may apply a search on the problem space to determine if a solution exists. In some exemplary embodiments, the CSP solver may apply backtracking, constraint propagation, local search, or the like. In some exemplary embodiments, the CSP solver may implement Very Large-scale Neighborhood Search (VLNS), linear programming, Maintaining Arc Consistency (MAC), or the like.

On Step 140, the solution of the CSP, provided by the CSP solver on Step 130, may be obtained and utilized to synthesize a quantum circuit. The synthesis may be based on the values of the decision variables in the solution, which may define which gates are connected to which qubits and in which cycles, as well as other parameters relevant for the creation of the circuit (e.g., angles related to different gates, controlling qubits, etc.).

On Step 150, the quantum circuit may be compiled by a compiler so as to provide a quantum program that can be executed on a specific type of target execution platform. In some exemplary embodiments, the compiler may predict small-scale functionality and replace it with a better implementation, as part of local optimizations. It is noted that the compiler may be unable to perform large scale optimizations, as such optimizations may require knowledge and understanding of the functionality of the circuit as a whole. It is noted that the same quantum circuit may be compiled to a different implementation for different execution platforms, such as in view of the gates available in the execution platform which are used to implement the functionality of the gates defined in the quantum circuit. Hence, the compiler may create a different quantum circuit having an equivalent functionality to that of the circuit generated on Step 140, potentially varying in performance.

On Step 160, the compiled quantum circuit is executed on the target execution platform, e.g., a target quantum computer. In some exemplary embodiments, the compiled circuit may be executed a plurality of times. On Step 170, the results of the execution(s) may be outputted, such as by providing an output to the user. In some exemplary embodiments, each execution may result in an output state. In some exemplary embodiments, an average or other aggregation may be performed on the plurality of output states. The aggregated state may be considered the output of the execution of the circuit. Additionally or alternatively, a specific state could be of interest without aggregation and may be outputted.

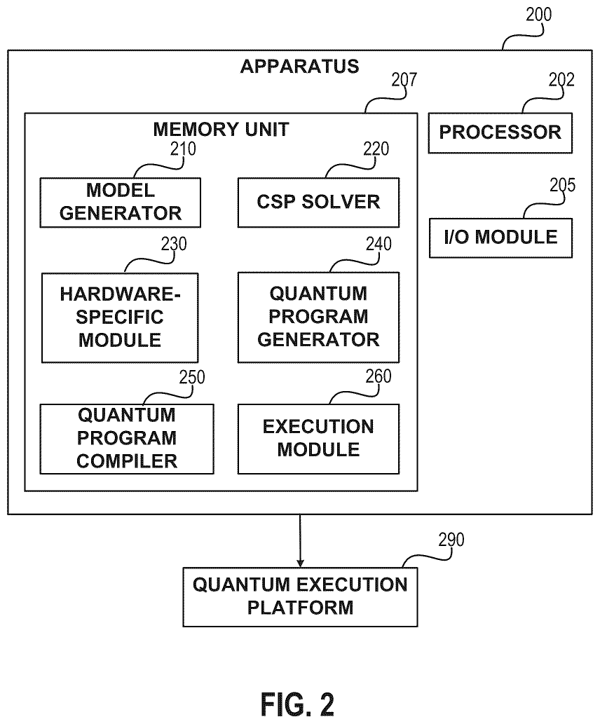

Referring now to FIG. 2 showing a block diagram of an apparatus, in accordance with some exemplary embodiments of the disclosed subject matter.

In some exemplary embodiments, Apparatus 200 may comprise one or more Processor(s) 202. Processor 202 may be a Central Processing Unit (CPU), a microprocessor, an electronic circuit, an Integrated Circuit (IC) or the like. Processor 202 may be utilized to perform computations required by Apparatus 200 or any of its subcomponents.

In some exemplary embodiments of the disclosed subject matter, Apparatus 200 may comprise an Input/Output (I/O) module 205. I/O Module 205 may be utilized to provide an output to and receive input from a user, such as, for example to obtain constraints, variables, definitions or the like from the user, from a third party, from an electronic record, or the like, to provide output such as electronic representation of the quantum circuit, a compiled quantum circuit, an output state resulting from the execution of the compiled circuit, an aggregated state of multiple output states resulting from the execution of the compiled circuit, or the like.

In some exemplary embodiments, Apparatus 200 may comprise Memory 207. Memory 207 may be a hard disk drive, a Flash disk, a Random Access Memory (RAM), a memory chip, or the like. In some exemplary embodiments, Memory 207 may retain program code operative to cause Processor 202 to perform acts associated with any of the subcomponents of Apparatus 200.

Memory 207 may comprise one or more components as detailed below, implemented as executables, libraries, static libraries, functions, or any other executable components.

In some exemplary embodiments, Model Generator 210 may be configured to generate a model of a quantum circuit. The model may be a CSP model. In some exemplary embodiments, the model may be generated based on user input, such as explicit instructions, commands, or the like. Additionally or alternatively, the model may be generated based on an initial model that is automatically augmented to introduce additional constraints, decision variables, or the like. In some exemplary embodiments, Hardware-Specific Module 230 may be invoked to add constraints and decision variables to the model based on the quantum execution platform upon which the circuit is to be executed, such as Quantum Execution Platform 290.

In some exemplary embodiments, CSP Solver 220 may be a tool that is capable of providing a satisfying solution to a CSP, optionally, while optimizing a target function, or indicating that such a solution does not exist. CSP Solver 220 may be utilized in Step 130 of FIG. 1, and Steps 530-540 of FIG. 5.

Quantum Program Generator 240 may be configured to obtain a solution provided by CSP Solver 220 and generate a quantum circuit based thereon. The solution may indicate, for example, which qubits are connected to which gates, and which cycle and various parameters regarding how they are connected. In some cases, the solution may indicate which types of gates are to be employed at each cycle, which qubit is controlling them or controlled by them, or the like. Such information may be utilized to generate a design of the quantum circuit. By Quantum Program Generator 240. In some exemplary embodiments, Quantum Program Generator 240 may be utilized to perform Step 140 of FIG. 1, Step 550 of FIG. 5, or the like.

Quantum Program Compiler 250 may obtain a quantum circuit, such as generated by Quantum Program Generator 240, and compile a concrete executable program that can be executed on specific quantum computer, such as Quantum Execution Platform 290. Quantum Program Compiler 250 may compile the circuit and modify it to adhere to the target quantum computer its type, available resources, or the like. Additionally or alternatively, Quantum Program Compiler 250 may perform small-scale, local, optimizations to the circuit design, before or after modifying the design to utilize the resources of Quantum Execution Platform 290. In some exemplary embodiments, Quantum Program Compiler 250 may be utilized to perform Step 150 of FIG. 1, Step 550 of FIG. 5, or the like.

Execution Module 260 may be configured to execute the compiled circuit on the target quantum computer, Quantum Execution Platform 290. In some exemplary embodiments, Execution Module 260 may be configured to execute the program once, and obtain the execution result, such as the output state provided by Quantum Execution Platform 290. Additionally or alternatively, Execution Module 260 may be configured to execute the program multiple times and obtain multiple output results. The results may then be aggregated together, such as by creating an averaged output state, which may be considered to be the output of the compiled quantum circuit. In some exemplary embodiments, Execution Module 260 may be utilized in performing Steps 160-170 of FIG. 1, to executed the synthesized circuit resulting from Step 550 of FIG. 5, or the like.

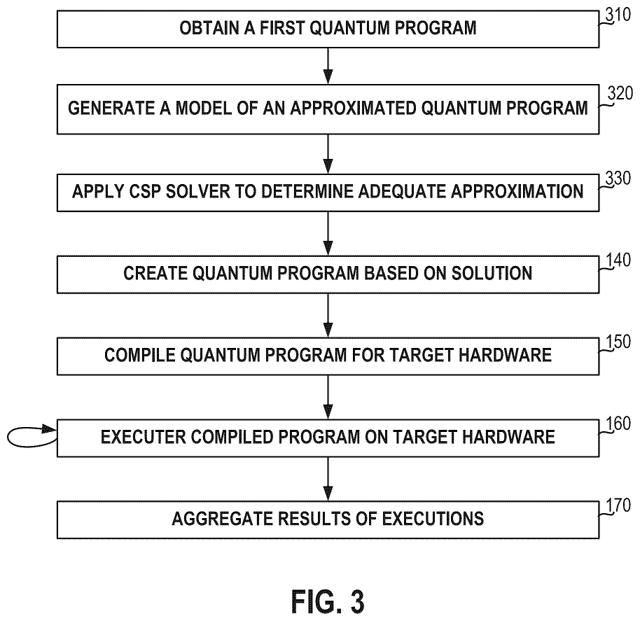

Referring now to FIG. 3, showing a flowchart diagram of a method, in accordance with some exemplary embodiments of the disclosed subject matter. FIG. 3 exemplifies a method in which advanced circuit design can be facilitated with CSP modeling by adding interesting properties and constraints about the gate assignment.

On Step 310, a first quantum program is obtained. The obtained quantum program may be provided in a compiled or non-compiled manner. The obtained quantum program may be generated automatically, designed manually, or the like. In some exemplary embodiments, the first quantum program may be an ideal program, which while theoretically correct, cannot be utilized in real life due to some constraints. The first quantum program may be denoted as U. In some exemplary embodiments, U may be a matrix of 2″·2″. U may be a unitary matrix, a matrix that is if multiplied by a vector with norm of 1, outputs a vector with norm of 1. In some cases, a unitary matrix may be a quantum program, in which unitary operations (gates) are applied on the qubits. Additionally or alternatively, valid quantum state, denoted as ψ, may be a vector of size 2″ with a norm of 1. The execution of the quantum program may be the multiplication of the state ψ by the unitary matrix U, resulting in an output state.

In some exemplary embodiments, it may be desired to provide an approximated program that adheres to some constraints and has desired properties, while providing an approximated solution within a maximum error threshold.

In some exemplary embodiments, some circuit properties that are of interest in the Noisy Intermediate-Scale Quantum (NISQ) era may be, for example, circuit depth, error, or the like. In some exemplary embodiments, the error may be caused due to decoherence. In some cases, as the circuit is deeper, the error may increase. In some exemplary embodiments, compromise in the circuit design may be desired: instead of using an exact implementation of an operation which using a circuit with large depth, one may use an approximated operation that has less depth but induces approximation error.

On Step 320, a model of the approximated quantum circuit may be obtained. In some cases, the model may be based on an initial model that may be provided by a third party, by a human user, or the like. In some exemplary embodiments, an initial model may be completed and augmented in an automated manner.

In some exemplary embodiments, the model may be a CSP model. In some exemplary embodiments, the CSP model may comprise a decision variable indicating the depth of the design. In some exemplary embodiments, after each gate assignment, the depth lower bound is propagated accordingly. Additionally or alternatively, a constraint creating a maximal bound (e.g., depth <N) may be introduced.

In some exemplary embodiments, the model may comprise a decision variable representing the error, referred to as “error variable”. The value of the error variable may be defined using an error metric. The value of the error variable may be calculated on each unitary operation and its implementation. As an example, the error metric may be a linear error metric, but it is noted that the disclosed subject matter is not limited to such implementation. For example, the metric

$$E ( U , V ) = {max}_{\vert ψ 〉} ‖ ( U * ψ - V * ψ ) \vert ψ 〉 ‖$$

is the maximum error for using unitary V (the approximated quantum circuit) instead of the first quantum circuit, unitary U. This metric may satisfy the property of: E(U₁U₂, V₁V₂)≤E(U₁, V₁)+E U₂, V₂). When such property is held, the value of the error variable can be computed, and a constraint can be introduced to the model to limit the maximal accepted circuit total error. In some exemplary embodiments, the user may introduce constraints on specific blocks of the quantum circuit, such as limiting error in the first block to be no more than a first threshold T₁, limiting error in the second block to be no more than a second threshold T₂, limiting error in the entire circuit to be no more than T₃, or the like.

On Step 330, the model may be solved, using a CSP solver, so as to determine a quantum circuit (V) that adheres to the constraints and which is an adequate approximation of the first quantum circuit (U). Such solution can then be used to generate the quantum program (140), which is compiled (150) and executed (160) to provide results (170).

In some exemplary embodiments, the disclosed subject matter may be employed for generating small gate designs. In some exemplary embodiments, the CSP modeling can be used to design small gate/block, such as a design of up to 10 qubits, 30 qubits, 50 qubits, or the like, that complies with certain properties. As an example, entanglement may be used to various algorithms so a gate which provides a level of entanglement can be useful. In some exemplary embodiments, to implement such circuit with the CSP, a decision variable containing the state vector is needed. The propagation of the state variable is done via a quantum simulator in the propagator of the CSP solver. In some exemplary embodiments, the entanglements between different qubits can be done by connecting them with CNOT gate and single qubit operation like Hadamard gate. The propagator may leave connected qubits untouched while applying operation in the subspace which is not yet connected.

In some exemplary embodiments, benchmarking or testing the quantum circuit hardware may be important for comparing between different hardware execution platforms or for diagnosing if specific execution platform is underperforming. In some exemplary embodiments, random circuits may be a good way to test blindly a quantum hardware, and can be tweaked to perform more intelligent tests if given the hardware architecture. One example is to create random circuits with a certain distribution of unitary gate (e.g., implemented by a constraint on gate count) available to the hardware. This may test if the gate operates correctly when applied in a different setting. Another example may be to stress test a specific area of the hardware by employing complicated operation on the section of interest. Yet another example is to test connectivity between distance qubits by assigning several two qubits gate between them. The specific implementation of the examples is not important. As a result, this allows the CSP to give a wide range of options, making the benchmark more robust.

It is noted that correctness of a large circuit (>50 qubits) can be verified by applying the benchmark circuit and then applying its inverse circuit so that the expected output is the zero state.

In some exemplary embodiments, discovering of ansatz for Variational Quantum Eigensolver (VQE) and Quantum Approximate Optimization Algorithm (QAOA) algorithms may be desired. An ansatz is a parametric quantum circuit. In some exemplary embodiments, the parameters of the ansatz may be tuned classically to reach the desired state at the output of the circuit. It is hard to find a useful ansatz because the search space is large. The CSP engine can help in the search when given simple construction patterns, provided as constraints on the model. The slide entangler is one example of a construction pattern. As an example, the CSP may hold the constraint by using one pattern out of a list of patterns that are known to create entanglement. Another example is that the user can define which entanglement pattern to use explicitly, but the location (cycle) and qubits on which it is applied is selected by the CSP solver. Sometimes this can overlap with other constraints and a single pattern may be used to uphold several constraints, reduce resources needed for another constraint, or the like.

In some exemplary embodiments, a model can constraint the gates to be only between ‘n’ qubits, that each qubit be used only ‘m’ times, to limit the depth of the ansatz, the number of parameters used, and more.

Each output ansatz be used in the VQE pr QAOA algorithm to determine if it is useful or not.

In some exemplary embodiments, multi-control gates may have two alternative implementations: the first requires O (n) gates with auxiliary qubits, while the second requires O(n²) gates with no auxiliary qubits. In some exemplary embodiments, the model may be held by either implementation, and the CSP solver may choose the implementation that meets all other constraints. In such a manner, the CSP solver can optimize run time over space and vice versa.

Additionally, or alternatively, the CSP can control the use of the use of auxiliary qubits and reuse them in a different part of the circuit by keeping a flag var for auxiliary usage. An auxiliary qubit is a qubit which start at the zero state, is used for some computation and after the computation it is back to the zero state and disconnected from the rest of the circuit. In each gate implementation, each auxiliary qubit is known by design. On the other hand, a compiler cannot know without simulation, which is computationally hard. The model may indicate for each qubit whether it is auxiliary. A decision variable may be added for each qubit indicating if it is auxiliary in each cycle. The CSP constraints can assign value to keep track of this and using this information, gates that require auxiliary qubits can select different qubits to be used. When a gate is placed on specific qubits, their respective flags may be indicated as false or true, depending on what role the qubit has in the gate, and whether, by design, the gate defines such qubits as auxiliary. As an example, consider a 3-qubit gate which uses 1 auxiliary. When such a gate is placed on 4 qubits in the model, the first 3 qubits are marked as false (not auxiliary) and the last one is marked as an auxiliary. It is noted that the model may require that only a qubit that is a-priori auxiliary can be given an auxiliary role in a gate. In some exemplary embodiments, all qubits may be initially considered as auxiliary as they are initialized to the zero state.

Referring now to FIGS. 4A-4G, showing exemplary compilations of quantum programs, in accordance with some exemplary embodiments of the disclosed subject matter.

In some exemplary embodiments, one or more quantum programs may be obtained and converted to a DAG (not depicted). In some exemplary embodiments, the DAG may comprise a plurality of nodes, with at least some of which being inexecutable. In some exemplary embodiments, during an in-line process, the nodes of the DAG may be converted, replaced, or the like, with node implementations from a function library.

In some exemplary embodiments, the function library may be adjusted to provide implementations of DAG nodes in different granularity levels. For example, instead of merely providing various gate-level implementations of DAG nodes, the function library may be adjusted to higher level implementations (e.g., lower granularity level implementations) such as DAG implementations for a node, partially inlined DAG implementations for a node, or the like. In some exemplary embodiments, providing implementations of a node in lower granularity levels than a gate-level implementation may be advantageous in many scenarios, e.g., as can be inferred from FIGS. 4A-4G. For example, FIGS. 4E and 4F depict scenarios of using gate-level implementations, while FIG. 4G depicts a scenario of using lower granularity level implementations.

In some exemplary embodiments, the nodes of the DAG may comprise at least a node representing two functions or functional areas of a quantum program. For example, the node may represent Functions 410 and 420, as depicted in FIG. 4A. In some exemplary embodiments, Functions 410 and 420 may comprise gate-level implementations of the node's functions with respective properties. For example, Function 410 may have a width of two qubits and a length of ten cycles, and Function 420 may have a width of two qubits and a length of three cycles. In other cases, Functions 410 and 420 may have any other dimensions in their gate-level implementations. It is noted that throughout FIGS. 4A-4G, the ‘width’ property may refer to the number of qubits, and the ‘length’ property may refer to the number of cycles.

In some exemplary embodiments, one of the qubits, in both Functions 410 and 420, may be reusable. For example, the grating pattern within Functions 410 and 420 may represent a reusable area, in which qubits can be shared with other circuits. In some exemplary embodiments, a reusable qubit may comprise an auxiliary or known qubit that may be used for one or more cycles and then cleaned so that other circuits may utilize the qubit subsequently.

In some exemplary embodiments, in order to execute Functions 410 and 420, they may be scheduled over a lattice of qubits and cycles of a quantum execution platform. In some exemplary embodiments, the manner in which Functions 410 and 420 are scheduled may affect the number of resources used by Functions 410 and 420. In some exemplary embodiments, the scheduling of Functions 410 and 420 may be obtained from one or more gate-level implementations of the node in a function library.

For example, the function library may comprise a scheduling of Functions 410 and 420 in which they are scheduled to be performed in parallel, as depicted in FIG. 4B. In this scenario, Functions 410 and 420 may each utilize two separate qubits, without reusing qubits or sharing qubit resources. The number of cycles required for executing Functions 410 and 420, when performed simultaneously, may be ten (e.g., the length of Function 410 being the bottleneck). According to this example, the overall resources that are required for executing Functions 410 and 420, may be referred to as the “area” of resources and may be calculated as follows:

$$A = L * W \qquad ( 1 )$$

where A denotes the area, L denotes the overall length in terms of cycles, and W denotes the overall width in terms of qubits. In the case of FIG. 4B, the overall resources for the depicted scheduling may be 40 (10*4, 10 being the overall length and 4 being the overall width).

As another example, the function library may comprise a scheduling of Functions 410 and 420 in which they are scheduled to be performed sequentially, as depicted in FIG. 4C. In this scenario, Functions 410 and 420 may share their reusable qubit, and allocate separate qubits for non-reusable areas. Thus, the overall width of the node implementation may be three (two non-reusable qubits and one reusable qubit). The reusable qubit may be first used by Function 410, and then provided to Function 420 to be reused thereby, e.g., as depicted in FIG. 4C. In other cases, the qubit may be reused in any other order, e.g., Function 420 may provide the reusable qubit to Function 410. According to this example, the overall resources that are required for executing Functions 410 and 420, may be 39 ((10+3)*3, 13 being the overall length and 3being the overall width). Thus, reusing qubits may reduce the resource consumption compared to the scenario of FIG. 4B.

In some cases, the compilation process may schedule Functions 410 and 420 according to a schedule available in the function library, according to an optimization function, or the like. For example, a CSP solver may select the scheduling of FIG. 4C due to its lower consumption of qubits, and provide the scheduled implementation as a black box that implements a respective node of the DAG. For example, the scheduling of FIG. 4C may be obtained from the function library as a packed and sealed black box, e.g., Function 400 in FIG. 4D, during the CSP solver execution.

In some exemplary embodiments, the inlining process of FIGS. 4B-4D may have one or more drawbacks, at least since it may use only gate-level implementations of the DAG's node. For example, the inlining process of FIGS. 4B-4D may adversely affect the resource consumption of the entire circuit resulting from the compilation. For example, after obtaining Function 400, the CSP solver may not have the flexibility to schedule Functions 410 and 420 in an optimal manner that reduces resources, resulting with a sub-optimal usage of resources, e.g., as depicted in FIGS. 4E-4F.

In some exemplary embodiments, FIG. 4D depicts a scenario in which a first node of the DAG is replaced with Function 400 (by the compilation process, and a second node of the DAG is replaced with an implementation of a second node, e.g., Function 430. For example, the second node may represent a function in a high level of abstraction, and Function 430 may be obtained from the function library, or dynamically generated, as a gate-level implementation of the function of the second node.

In some cases, the dimensions of Function 430 may correspond to Function 420 of FIG. 4C, and may have a width of 2 qubits and a length of 3 cycles, one of the qubits being reusable. In other cases, Function 430 may have any other dimensions. In some exemplary embodiments, Function 400 may correspond to the sequential scheduling of Functions 410 and 420, and may utilize an overall area of 39 resource units.

In some exemplary embodiments, as part of the compilation process, the node implementations may be scheduled over the space of qubits and cycles. For example, Functions 400 and 430 may be scheduled in parallel, sequentially, or the like. In some exemplary embodiments, the scheduling of Functions 400 and 430 may be obtained from the function library, or in any other way.

For example, the function library may comprise a scheduling of Functions 400 and 430 in parallel, as depicted in FIG. 4E. In this scenario, Functions 400 and 430 may utilize five separate qubits, without reusing or sharing qubits. The number of cycles required for executing Functions 400 and 430, when performed simultaneously, may be thirteen (e.g., the length of Function 400). According to this example, the overall resource units that are required for executing this scheduling of Functions 400 and 430 may be 65 (13*5, 13 being the overall length and 5 being the overall width).

As another example, the function library may comprise a scheduling of Functions 400 and 430 in sequentially, as depicted in FIG. 4F. In this scenario, Functions 400 and 430 may share a reusable qubit, and separate qubits may be allocated for non-reusable qubits. Thus, the overall width may be four (three non-reusable qubits and one reusable qubit). The reusable qubit may be first used by Function 400, and then provided to Function 430 to be reused thereby, e.g., as depicted in FIG. 4F. In other cases, the qubit may be reused in any other order, e.g., Function 430 may provide the reusable qubit to Function 400, without affecting the overall resource consumption. According to this example, the overall resources that are required for executing this scheduling of Functions 400 and 430 may be 64 ((13+3)*4, 16 being the overall length and 4 being the overall width).

In some exemplary embodiments, instead of using gate-level implementations of nodes, such as Function 400, the disclosed subject matter provides node implementations in lower granularity levels. In some exemplary embodiments, reducing the granularity level may enable to reduce the resources consumed in both sequential and parallel scenarios of FIGS. 4E-4F. In some exemplary embodiments, instead of implementing each node of the program's DAG as a gate-level implementation, resulting in Functions 400 and 430, the nodes may be implementable in lower granularity levels, thereby increasing flexibility. For example, instead of implementing a node of the program's DAG as a gate-level black box that is non-adjustable, e.g., Function 400, the node may be implemented in a lower granularity level that includes a DAG with its components, e.g., Functions 410 and 420 as nodes of a second DAG. For example, a full or partial DAG implementing the node may comprise Function 410 as a first node and Function 420 as a second node, and an edge between them indicating a precedence constraint.

In some exemplary embodiments, decomposing Function 400 into its components, as enabled by the lower granularity level implementations, may increase the scheduling options that the CSP solver can select. For example, in case the CSP solver selects from the function library a lower granularity level implementation of the node that includes Functions 410 and 420, the CSP solver may be enabled to select a scheduling of Functions 410, 420, and 430, as separate entities.

In some exemplary embodiments, FIG. 4G depicts an exemplary scheduling of Functions 410, 420, and 430, that may be provided by the function library and selected by the CSP solver. In some exemplary embodiments, Functions 410, 420, and 430 may be scheduled such that Function 410 may be performed in parallel to Functions 420 and 430, while Functions 420 and 430 may be scheduled to be performed sequentially. According to this scheduling, the overall resources, or area, of the execution may be 50 (10*5, 10 being the overall length and 5 being the overall width), which is 14 resource units less than the scheduling of FIG. 4F, and 15 resource units less than the scheduling of FIG. 4E. Thus, the disclosed subject matter dramatically reduces the resources used for executions of DAG node implementations of a program.

In other cases, Functions 410, 420, and 430 may be scheduled by the CSP solver in any other way, such as by scheduling Function 430 between Functions 410 and 420, or the like.

Referring now to FIG. 5, showing a flowchart diagram of a method, in accordance with some exemplary embodiments of the disclosed subject matter.

On Step 510, one or more quantum programs may be obtained. For example, a quantum program may be obtained from a user, a programmer, a server, a computing device, or the like.

On Step 520, the quantum program may be converted into a DAG representation, as part of a compilation process. In other cases, the DAG representation may be obtained instead of the quantum program, e.g., from a user, a compiler, a server, or the like.

In some exemplary embodiments, the DAG representation may comprise a plurality of nodes, one or more edges between the nodes, or the like. In some exemplary embodiments, the edges between the nodes may indicate precedence constraints between the nodes, precedence constraints between nodes' functionalities, or the like.

In some exemplary embodiments, the plurality of nodes may comprise at least one non-executable node that represents a functionality of the quantum program. For example, the non-executable node may comprise high-level representations of the functionality, and may not be executable over a quantum execution platform. In some exemplary embodiments, in addition to the non-executable node, the DAG representation may comprise one or more nodes that are executable, one or more node that are not executable but have a different level of granularity than the non-executable node, or the like. For example, the DAG representation may comprise an executable node in a gate-level granularity, e.g., including a gate-level representation.

On Step 530, the DAG representation may be processed to select, for each node of the DAG, a respective implementation in a selected granularity level. In some exemplary embodiments, implementations may be selected from a function library, dynamically generated, or the like, and may inline or replace at least some nodes of the DAG.

In some exemplary embodiments, a CSP model of the DAG representation may be generated to represent the quantum program using a variables, domains, and constraints on values of the variables. For example, the constraints may comprise hardware constraints of a quantum execution platform over which the quantum program is scheduled to be executed.

In some exemplary embodiments, a partial DAG representation may be generated based on the DAG representation, e.g., by executing a CSP solver may be executed over the CSP model. In some exemplary embodiments, during the execution of the CSP solver, the CSP solver may select an implementation of the non-executable node in the DAG representation. For example, the implementation of the non-executable node may comprise at least a first executable node and a second non-executable node, that together implement the non-executable node. According to this example, the first executable node may be in a second level of granularity that is greater than the first level of granularity, e.g., a gate-level granularity that is executable over the quantum execution platform. In some cases, the second non-executable node may be in one or more levels of granularity than are not executable, e.g., a DAG level of granularity, a partial DAG level of granularity (also referred to as ‘hybrid DAG level of granularity’), or the like.

In some exemplary embodiments, during the execution of the CSP solver, the granularity level for each node may be selected from available granularity levels in a function library. In some exemplary embodiments, the function library may comprise implementations of different high-level functionalities in different levels of granularity, e.g., in a DAG level of granularity, a partial DAG level of granularity, a gate-level granularity, or the like. In some exemplary embodiments, node implementations may be provided in first, second, or third levels of granularity. For example, the first level of granularity may comprise a gate-level granularity, the second level of granularity may comprise a DAG level of granularity, and the third level of granularity may comprise a partial (hybrid) DAG level of granularity. In some cases, multiple third levels of granularity may defined to correspond to a range of partial DAG granularities, each encompassing a different percentage of gate-level implementations.

In some exemplary embodiments, an implementation of a node in the DAG level of granularity may comprise a high-level implementation that is not executable over the quantum execution platform. For example, implementing a node in the DAG level of granularity may comprise replacing the node with a DAG implementation in which all of the nodes are not executable.

In some exemplary embodiments, an implementation of a node in the partial DAG level of granularity may comprise a high-level implementation that is not executable over the quantum execution platform. For example, implementing a node in the partial DAG level of granularity may comprise replacing the node with a DAG implementation in which some nodes are not executable and some nodes are executable. For example, the nodes that are executable may comprise nodes with gate-level implementations.

In some exemplary embodiments, the function library may store, for a node, two or more implementations in the partial DAG level of granularity, two or more implementations in the DAG level of granularity, two or more implementations in the gate level granularity, or the like.

In some exemplary embodiments, after selecting a granularity level for a node, a library implementation in the selected granularity level may be selected from the function library and replaced with the node. For example, in case the selected granularity level has four available implementations of the node, one may be selected. In some cases, a library implementation of a node may be selected in a granularity level as a single step, without first selecting its granularity level.

On Step 540, after selecting implementations for each node in a selected granularity, such as using the CSP solver, the nodes may be scheduled over a qubit-cycle space. In some exemplary embodiments, scheduling the node implementation may enable nodes to share resources, such as auxiliary qubit resources.

In some exemplary embodiments, Steps 530-540 may be performed iteratively, such as by generating a CSP model for each resulting DAG, and executing a CSP solver over the resulting DAG, until the CSP model is automatically solved. In some exemplary embodiments, the CSP model is solved when the CSP solver provides all the valuations of the variables that comply with the constraints. In some exemplary embodiments, the determined valuations may represent a gate-level DAG in which all nodes of the DAG are executable in a gate-level granularity and are scheduled over the qubit-cycle space. For example, in case the CSP solver replaces a node of the DAG with a second DAG, the CSP solver may be executed again on the resulting DAG, causing the second DAG to be replaced with a partial DAG, a different full DAG, a gate-level implementation, or the like, until eventually all DAG nodes are converted to a gate-level implementation.

On Step 550, a quantum circuit resulting from the iterative process of Steps 530-540 may be synthesized and executed on the quantum execution platform, e.g., a quantum computer, cloud, or the like. For example, the quantum circuit may comprise the scheduled gate-level implementation of the DAG, represented by a valuation determined by the CSP solver. For example, the quantum circuit may be synthesized based on the valuation, and the synthesized quantum circuit may be executed on the quantum execution platform.

Referring now to FIG. 6, showing a flowchart diagram of a method, in accordance with some exemplary embodiments of the disclosed subject matter.

On Step 610, a library of implementations of non-executable DAG nodes may be generated. For example, the library may correspond to the function library of FIG. 5.

In some exemplary embodiments, the library may be generated to comprise node implementations in different granularity levels. For example, the library may comprise, for a specific node of a DAG (e.g., a non-executable DAG node in a lower granularity than the gate-level granularity), a set of implementations in a DAG level of granularity, a partial DAG level of granularity, a gate-level granularity, or the like, e.g., similarly to granularity levels described in Step 530 of FIG. 5.

In some exemplary embodiments, the library may be generated to comprise a plurality of node implementations for a single level of granularity. For example, two node implementations may implement a node in a partial DAG granularity using different resource allocations. As another example, two node implementations may implement a non-executable DAG node in the gate-level granularity, e.g., using different resource allocations, designing the implementations for execution at different quantum execution platforms, or the like.

In some exemplary embodiments, the library may be generated to comprise node implementations based on previous compilations, based on shared databases, metadata, using dynamic generation of implementations, or the like.

On Step 620, the library may obtain a selection of a node implementation for each node of a DAG, e.g., from a CSP solver. For example, the CSP solver may be automatically executed over a CSP model that represents a quantum program, according to a DAG representation of the quantum program. In some exemplary embodiments, the CSP solver may select, for each node of a DAG, a respective node implementation in a respective level of granularity.

On Step 630, for each selection of a node implementation, the node may be converted, replaced, or inlined, with the node implementation, thereby providing an adjusted DAG. For example, the compiler may convert the nodes with their selected implementations according to valuations of the CSP solver, and schedule them over a qubit-cycle space.

In some exemplary embodiments, the CSP solver may be iteratively executed over the nodes of the DAG, to select implementations for each node on Step 620 and adjust the DAG accordingly, until all nodes of the DAG have an executable implementation in a gate-level granularity that is scheduled over the qubit-cycle space.

In some cases, adjusted DAGs generated on Step 630 may or may not be used to adjust the library, such as by adding node implementations thereto.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A method comprising:
obtaining a Directed Cycle Graph (DAG) representation of a quantum program, the DAG representation comprises a plurality of nodes and one or more edges, the plurality of nodes comprises at least one non-executable node that represents a functionality in a high-level representation, the at least one non-executable node is not executable over a quantum execution platform, the high-level representation comprising a first level of granularity, the one or more edges indicates precedence constraints between the plurality of nodes;
generating a Constraint Satisfaction Problem (CSP) model of the DAG representation, the CSP model representing the quantum program using variables, domains, and constraints on values of the variables;
generating a partial DAG representation of the quantum program based on the DAG representation, the partial DAG representation comprising at least a first executable node and a second non-executable node, the first executable node is in a second level of granularity greater than the first level of granularity, said generating comprising executing a CSP solver over the CSP model, wherein said executing comprises selecting the first executable node and the second non-executable node as implementations of the at least one non-executable node; and
synthesizing the quantum program based on the partial DAG representation, said synthesizing comprises determining a gate-level implementation of the quantum program based on the partial DAG representation, thereby obtaining a synthesized quantum circuit.

2. The method of claim 1, wherein said synthesizing comprises:
generating a second CSP model of the partial DAG representation;
generating a second partial DAG representation of the quantum program based on the partial DAG representation, the second partial DAG representation comprising an executable gate-level implementation of the second non-executable node, the executable implementation is in the second level of granularity, said generating the second partial DAG representation comprising executing the CSP solver over the second CSP model, wherein said executing comprises selecting the executable gate-level implementation for implementing the second non-executable node; and
synthesizing the quantum program based on the second partial DAG representation.

3. The method of claim 1, wherein the second non-executable node is in the first level of granularity, said synthesizing comprises:
generating a second CSP model of the partial DAG representation;
generating a second partial DAG representation of the quantum program based on the partial DAG representation, the second partial DAG representation comprising an implementation of the second non-executable node in a third level of granularity, the third level of granularity is a higher level of granularity that the first level of granularity, the third level of granularity is a lower level of granularity that the second level of granularity, said generating the second partial DAG representation comprising executing the CSP solver over the second CSP model, wherein said executing comprises selecting the implementation of the second non-executable node; and
synthesizing the quantum program based on the second partial DAG representation.

4. The method of claim 1, wherein said synthesizing the quantum program comprises iteratively executing the CSP solver over CSP models that are generated to represent the quantum program, wherein said iteratively executing is performed until obtaining valuations of all the variables from the domains, the valuations comply with the constraints, wherein the valuations represent the gate-level implementation of the quantum program in the second level of granularity.

5. The method of claim 1 further comprising scheduling the first executable node and the second non-executable node over a space of qubits and cycles, wherein said scheduling configures the first executable node and the second non-executable node to share one or more auxiliary qubits.

6. The method of claim 1, wherein said selecting comprising selecting a partial DAG level of granularity for implementing the at least one non-executable node, the partial DAG level of granularity comprises a second plurality of nodes, the second plurality of nodes comprising at least the first executable node and the second non-executable node.

7. The method of claim 1, wherein the first level of granularity comprises a DAG level of granularity, wherein an implementation of a DAG node in the first level of granularity comprises an implementation that is not executable, wherein the implementation of the DAG node comprises a second DAG having a second plurality of nodes, the second plurality of nodes is not executable.

8. The method of claim 1, wherein the first level of granularity comprises a partial DAG level of granularity, wherein an implementation of a DAG node in the first level of granularity comprises a second DAG having a second plurality of nodes, the second plurality of nodes comprise a first portion that is executable and a second portion that is not executable.

9. The method of claim 1, wherein the second level of granularity comprises a gate-level granularity that is executable over the quantum execution platform.

10. The method of claim 1, wherein the implementations of the at least one non-executable node are selected from a library of implementations, the library comprises implementations of the functionality in different levels of granularity, the different levels of granularity comprising at least the first and second levels of granularity.

11. The method of claim 10, wherein the different levels of granularity comprise a third level of granularity, wherein the first level of granularity is a DAG level of granularity and the third level of granularity is a partial DAG level of granularity.

12. The method of claim 11, wherein the second non-executable node is in the first level of granularity or in the third level of granularity.

13. The method of claim 1, wherein the constraints comprise hardware constraints of the quantum execution platform over which the synthesized quantum circuit is scheduled to be executed.

14. The method of claim 1, wherein said obtaining the DAG representation comprises obtaining the quantum program and compiling the quantum program to obtain the DAG representation.

15. The method of claim 1 further comprising executing the synthesized quantum circuit on the quantum execution platform.

16. An apparatus comprising a processor and coupled memory, said processor being adapted to:
obtain a Directed Cycle Graph (DAG) representation of a quantum program, the DAG representation comprises a plurality of nodes and one or more edges, the plurality of nodes comprises at least one non-executable node that represents a functionality in a high-level representation, the at least one non-executable node is not executable over a quantum execution platform, the high-level representation comprising a first level of granularity, the one or more edges indicates precedence constraints between the plurality of nodes;
generate a Constraint Satisfaction Problem (CSP) model of the DAG representation, the CSP model representing the quantum program using variables, domains, and constraints on values of the variables;
generate a partial DAG representation of the quantum program based on the DAG representation, the partial DAG representation comprising at least a first executable node and a second non-executable node, the first executable node is in a second level of granularity greater than the first level of granularity, said generate comprising executing a CSP solver over the CSP model, wherein said executing comprises selecting the first executable node and the second non-executable node as implementations of the at least one non-executable node; and
synthesize the quantum program based on the partial DAG representation, said synthesize comprises determining a gate-level implementation of the quantum program based on the partial DAG representation, thereby obtaining a synthesized quantum circuit.

17. The apparatus of claim 16, wherein said synthesize the quantum program comprises iteratively executing the CSP solver over CSP models that are generated to represent the quantum program, wherein said iteratively executing is performed until obtaining valuations of all the variables from the domains, the valuations comply with the constraints, wherein the valuations represent the gate-level implementation of the quantum program in the second level of granularity.

18. A method comprising:
generating a library of implementations of non-executable Directed Cycle Graph (DAG) nodes, wherein said generating comprises generating, for a non-executable DAG node, a set of implementations in at least two levels of granularity, the at least two levels of granularity comprise at least two of: a DAG level of granularity, a partial DAG level of granularity, and a gate-level granularity, wherein:
the DAG level of granularity comprises an implementation of the non-executable DAG node in a form of a first DAG with first nodes, wherein all nodes of the first DAG are not executable over a quantum execution platform;
the partial DAG level of granularity comprises an implementation of the non-executable DAG node in a form of a second DAG with second nodes, wherein a first portion of the second nodes is executable over the quantum execution platform and a second portion of the second nodes is not executable over the quantum execution platform; and
the gate-level granularity comprises a gate-level implementation of the non-executable DAG node that is executable over the quantum execution platform;
obtaining a selection of a node implementation from the set of implementations in a selected level of granularity, the selected level of granularity is selected from the at least two levels of granularity; and
replacing the non-executable DAG node with the node implementation.

19. The method of claim 18, wherein the set of implementations comprises at least two implementations of the non-executable DAG node having a same level of granularity.

20. The method of claim 19, wherein the quantum execution platform comprises first and second quantum execution platforms, wherein the at least two implementations comprise at least first and second implementations in the gate-level granularity that are executable over the first and second quantum execution platforms, respectively.

21. The method of claim 18, wherein the selection of the node implementation is made by a Constraint Satisfaction Problem (CSP) solver that is automatically executed over a CSP model, wherein the CSP model represents a quantum program, wherein a DAG representation of the quantum program comprises at least the non-executable DAG node.

22. The method of claim 18, wherein the non-executable DAG node is in a lower level of granularity than the gate-level granularity.

23. A computer program product comprising a non-transitory computer-readable medium retaining program instructions, which program instructions, when executed by a processor, cause the processor to:
generate a library of implementations of non-executable Directed Cycle Graph (DAG) nodes, wherein said generate comprises generating, for a non-executable DAG node, a set of implementations in at least two levels of granularity, the at least two levels of granularity comprise at least two of: a DAG level of granularity, a partial DAG level of granularity, and a gate-level granularity, wherein:
the DAG level of granularity comprises an implementation of the non-executable DAG node in a form of a first DAG with first nodes, wherein all nodes of the first DAG are not executable over a quantum execution platform;
the partial DAG level of granularity comprises an implementation of the non-executable DAG node in a form of a second DAG with second nodes, wherein a first portion of the second nodes is executable over the quantum execution platform and a second portion of the second nodes is not executable over the quantum execution platform; and
the gate-level granularity comprises a gate-level implementation of the non-executable DAG node that is executable over the quantum execution platform;
obtain a selection of a node implementation from the set of implementations in a selected level of granularity, the selected level of granularity is selected from the at least two levels of granularity; and
replace the non-executable DAG node with the node implementation.

24. The computer program product of claim 23, wherein the selection of the node implementation is made by a Constraint Satisfaction Problem (CSP) solver that is automatically executed over a CSP model, wherein the CSP model represents a quantum program, wherein a DAG representation of the quantum program comprises at least the non-executable DAG node.
